(19) United States
(12) Patent Application Publication
(10) Pub. No.: US 2023/0370082 A1
(43) Pub. Date: Nov. 16, 2023

(54) SHARED COLUMN ADCS FOR IN-MEMORY-COMPUTING MACROS

(71) Applicant: The Trustees of Princeton University, Princeton, NJ (US)

(72) Inventors: Jinseok LEE, Princeton, NJ (US); Naveen VERMA, Princeton, NJ (US); Hossein VALAVI, Princeton, NJ (US); Hongyang JAI, Princeton, NJ (US)

(73) Assignee: The Trustees of Princeton University, Princeton, NJ (US)

(21) Appl. No.: 17/745,322

(22) Filed: May 16, 2022

(51) Int. Cl. H03M 1/12; G11C 11/412

(52) U.S. Cl. CPC H03M 1/1245; G11C 11/412; G11C 11/413

(57) ABSTRACT

Various embodiments comprise systems, methods, architectures, mechanisms, apparatus, and improvements thereof for scaling and summing a plurality of weighted-data-representative analog signals provided by columns of in-memory computing bit cells within an N×M array of bit cells such that analog accumulation or summation of the weighted-data-representative analog signals provides a scaled result for further processing.

### CROSS-REFERENCE TO RELATED APPLICATION

This application is related to U.S. patent application Ser. No. 17/221,399, filed Apr. 2, 2021, which is a continuation in part of U.S. patent application Ser. No. 17/252,521, which claims the benefit of U.S. Provisional Patent Application Ser. Nos. 62/686,296 filed Jun. 18, 2018, 62/702,629 filed Jul. 24, 2018, 62/754,805 filed Nov. 2, 2018, and 62/756,951 filed Nov. 7, 2018, which Applications are all incorporated herein by reference in their entireties.

### FIELD OF THE DISCLOSURE

The present invention relates to the field of in-memory computing and, more particularly, to the scaling, summation, and conversion to digital data of analog signals representing weighted data such as provided by multiple parallel output of an array of in-memory computing cells.

### BACKGROUND

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

Charge-domain in-memory computing (IMC) has recently emerged as a robust and scalable way of doing in-memory computing. Here, compute operations within memory bit-cells provide their results as charge, typically using voltage-to-charge conversion via a capacitor. Thus, bit-cell circuits involve appropriate switching of a local capacitor in a given bit-cell, where that local capacitor is also appropriately coupled to other bit-cell capacitors, to yield an aggregated compute result across the coupled bit-cells. In-memory computing is well suited to implementing matrix-vector multiplication, where matrix elements are stored in the memory array, and vector elements are broadcast in parallel fashion over the memory array.

Advantageously, rather than acquiring individual bits one-at-a-time as done in conventional memory, an IMC computing architecture acquires computational results over many bits stored in memory. This enhances system energy efficiency and speed by reducing the number of data acquisition cycles required. Often, a computational result is derived within a memory column, where: parallel input data is provided to the rows, computation (e.g., multiplication) is performed by the memory bit cells with data stored therein; and further computation (e.g., accumulation) is performed on the column bit lines to provide reduction to a single output. The reduced output generally has increased dynamic range (i.e., number of signal levels) that need to be resolved, relative to single-bit accessing. Further, analog operation is often employed for the column computation, both to fit computation within the constrained memory circuits (e.g., bit cells, bit lines) and to enable the increased dynamic range. This necessitates for each column an analog-to-digital converter (ADC), in order to convert the column's analog output to a digital representation, suitable for further processing within an architecture.

### SUMMARY

Various deficiencies in the prior art are addressed by systems, methods, architectures, mechanisms, apparatus, and improvements thereof for scaling and summing a plurality of weighted-data-representative analog signals provided by columns of in-memory computing bit cells within an N×M array of bit cells such that analog accumulation or summation of the weighted-data-representative analog signals provides a scaled result for further processing.

Each bit cell provides at a respective output element (e.g., an output capacitor) a result of an operation during a measurement or evaluation phase, the result having associated with it a weight based upon the position of the bit cell in a row of bit cells (e.g., binary or other weighting from LSB to MSB of a result) such that each bit cell within a column of bit cells is associated with the same weight.

Analog signals (e.g., voltage or charge) associated with each column are scaled during a scaling phase in accordance with respective column weight such that a summation or accumulation of the scaled analog signals (e.g., voltage or charge) provides an accumulated/summation analog signal including an analog domain representation of an in-memory computing result, which is then subjected to analog to digital conversion (ADC) and further processing.

The scaling phase may comprise disconnecting some of the bit cells within a column of bit cells in accordance with the corresponding weighting value of that column such that, when the charge levels of the remaining bit cells within each column (e.g., their output capacitors) are accumulated to provide the accumulated/summation analog signal, the charge contributed thereto by each column is proportional to the weighting value of that column.

The scaling phase may comprise a signal divider such as a charge divider or charge divider network wherein the total charge provided by bit cells within a column of bit cells is divided to provide a charge level or analog signal representative thereof in accordance with the corresponding weighting value of that column. This may be performed prior to ADC such that an accumulated/summation analog signal presented to the ADC is appropriately scaled, or it may be performed in conjunction with sample and hold (S/H) of the ADC, such as by selective switching of charge divider elements of a successive approximation ADC.

Some embodiments provide an apparatus for scaling and summing a plurality of weighted-data-representative analog signals, wherein each analog signal comprises a voltage associated with a respective plurality of coupled bit-cell outputs within an in-memory computing (IMC) array of bit-cells, the apparatus comprising: a plurality of charge divider circuits, each charge divider circuit configured to process a respective weighted-data-representative analog signal to produce an output signal across a respective output capacitor of a capacitance value scaled in accordance with the respective weighting value; wherein, during a measurement phase of operation, the output capacitors of the charge divider circuits are coupled to a sample and hold circuit associated with an input of an analog to digital converter (ADC) configured to generate therefrom a digital output representing a summation of the weighted-data-representative analog signals.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 graphically depicts a typical structure of an in-memory computing architecture;

FIG. 2 depicts a block diagram of a fully row/column-parallel (1152 row×256 col) array of multiplying bit-cells (M-BCs) of an in-memory-computing (IMC) macro enabling N-bit (5-bit) input processing;

FIG. 3 depicts a circuit architecture of a multiplying bit cell suitable for use in the array of M-BCs of FIG. 2;

FIGS. 4A-4B graphically depict mechanisms for scaling and summation of computational result indicative outputs useful in illustrating the various embodiments;

FIGS. 4C-4D graphically depict mechanisms for scaling and summation of computational result indicative outputs useful in illustrating the various embodiments;

FIG. 5 graphically illustrates an exemplary IMC column within an array of M-BCs;

FIG. 6 graphically depicts an example of binary-weighted scaling within a bit-cell array of an in-memory computing architecture useful in understanding the embodiments;

FIGS. 7-9 depict circuit diagrams of various embodiments of binary-weighted scaling proximate or within an output ADC of an in-memory computing architecture; and

FIG. 10 depicts circuit diagrams of various embodiments of binary-weighted current divider scaling circuitry suitable for use in the various embodiments.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

Before the present invention is described in further detail, it is to be understood that the invention is not limited to the particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, a limited number of the exemplary methods and materials are described herein. It must be noted that as used herein and in the appended claims, the singular forms “a”, “an”, and “the” include plural referents unless the context clearly dictates otherwise.

The various embodiments will be discussed within the context of an IMC computing architecture acquiring computational results over many bits stored in memory, such as computational results derived within memory columns, where: parallel input data is provided to the rows, computation (e.g., multiplication) is performed by the memory bit cells with data stored therein; and further computation (e.g., accumulation) is performed on the column bit lines to provide at each column bit line a respective analog output signal representing a computational result associated with the respective bit line, illustratively described herein as being provided as a charge level though in alternate embodiments the column analog output may comprise a current level or voltage level.

Some of the various embodiments are directed to IMC computing architecture, apparatus, methods, and portions thereof configured to acquire the computational result indicative outputs of multiple parallel columns or bit lines in a manner avoiding the use of individual analog-to-digital converters (ADCs) for each column or bit line. That is, rather than converting the analog output signal associated with each bit line or column to a respective digital representation suitable for further processing within the IMC computing architecture, the various embodiments perform some of this further processing using the analog output signals associated with the bit lines or columns so as to reduce the number of ADCs needed to implement the functions of the IMC computing architecture while retaining analog output signal accuracy (i.e., reducing the impact of ADC quantization errors and other errors).

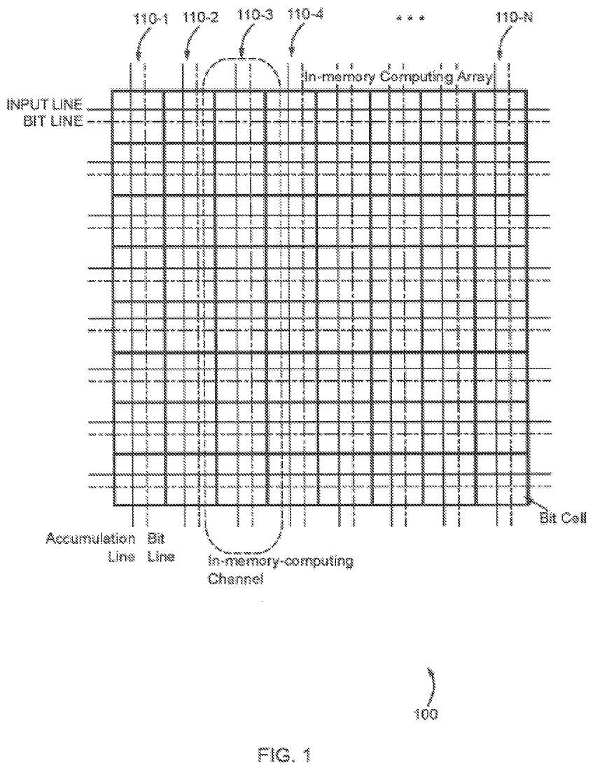

FIG. 1 graphically depicts a typical structure of an in-memory computing architecture. Specifically, the in-memory computing architecture 100 of FIG. 1 as depicted consists of a memory array (which could be based on standard bit-cells or modified bit-cells), in-memory computing involves two additional, “perpendicular” sets of signals; namely, (1) input lines; and (2) accumulation lines. Referring to FIG. 1, it can be seen that a two-dimensional array of bit cells is depicted, where each of a plurality of in-memory-computing channels 110-1 through 110-N (collectively in-memory-computing channels 110) comprises a respective column of bit-cells where each of the bit cells in a channel is associated with a common accumulation line and bit line (column), and a respective input line and word line (row). It is noted that the columns and rows of signals are denoted herein as being “perpendicular” with respect to each other to simply indicate a row/column relationship within the context of an array of bit cells such as the two-dimensional array of bit-cells depicted in FIG. 1. The term “perpendicular” as used herein is not intended to convey any specific geometric relationship.

The input/bit and accumulation/bit sets of signals may be physically combined with existing signals within the memory (e.g., word lines, bit lines) or could be separate. For implementing matrix-vector multiplication, the matrix elements are first loaded in the memory cells. Then, multiple input-vector elements (possibly all) are applied at once via the input lines. This causes a local compute operation, typically some form of multiplication, to occur at each of the memory bit-cells. The results of the compute operations are then driven onto the shared accumulation lines. In this way, the accumulation lines represent a computational result over the multiple bit-cells activated by input-vector elements. This is in contrast to standard memory accessing, where bit-cells are accessed via bit lines one at a time, activated by a single word line.

In-memory computing as described, has a number of important attributes. First, compute is typically analog. This because the constrained structure of memory and bit-cells requires richer compute models than enabled by simple digital switch-based abstractions. Second, the local operation at the bit-cells typically involves compute with a 1-b representation stored in the bit-cell. This is because the bit-cells in a standard memory array do not couple with each other in any binary-weighted fashion; any such coupling must be achieved by methods of bit-cell accessing/readout from the periphery. Below, the extensions on in-memory computing proposed in the invention are described.

While in-memory computing has the potential to address matrix-vector multiplication in a manner that conventional digital acceleration falls short, typical compute pipelines will involve a range of other operations surrounding matrix-vector multiplication. Typically, such operations are well addressed by conventional digital acceleration; nonetheless, it may be of high value to place such acceleration hardware near the in-memory-compute hardware, in an appropriate architecture to address the parallel nature, high throughput (and thus need for high communication bandwidth to/from), and general compute patterns associated with in-memory computing. Since much of the surrounding operations will preferably be done in the digital domain, analog-to-digital conversion via ADCs is included following each of the in-memory computing accumulation lines, which we thus refer to as an in-memory-computing channels. A primary challenge is integrating the ADC hardware in the pitch of each in-memory-computing channel, but proper layout approaches taken in this invention enable this.

Introducing an ADC following each compute channel enables efficient ways of extending in-memory compute to support multi-bit matrix and vector elements, via bit-parallel/bit-serial (BPBS) compute, respectively. Bit-parallel compute involves loading the different matrix-element bits in different in-memory-computing columns. The ADC outputs from the different columns are then appropriately bit shifted to represent the corresponding bit weighting, and digital accumulation over a set of the columns is performed to yield the multi-bit matrix-element compute result. Bit-serial compute, on the other hand, involves apply each bit of the input vector elements one at a time, storing the ADC outputs each time and bit shifting the stored outputs appropriately, before digital accumulation with the next outputs corresponding to subsequent input-vector bits. Such a BPBS approach, enabling a hybrid of analog and digital compute, is highly efficient since it exploits the high-efficiency low-precision regime of analog (1-b) with the high-efficiency high-precision regime of digital (multi-bit), while overcoming the accessing costs associated with conventional memory operations.

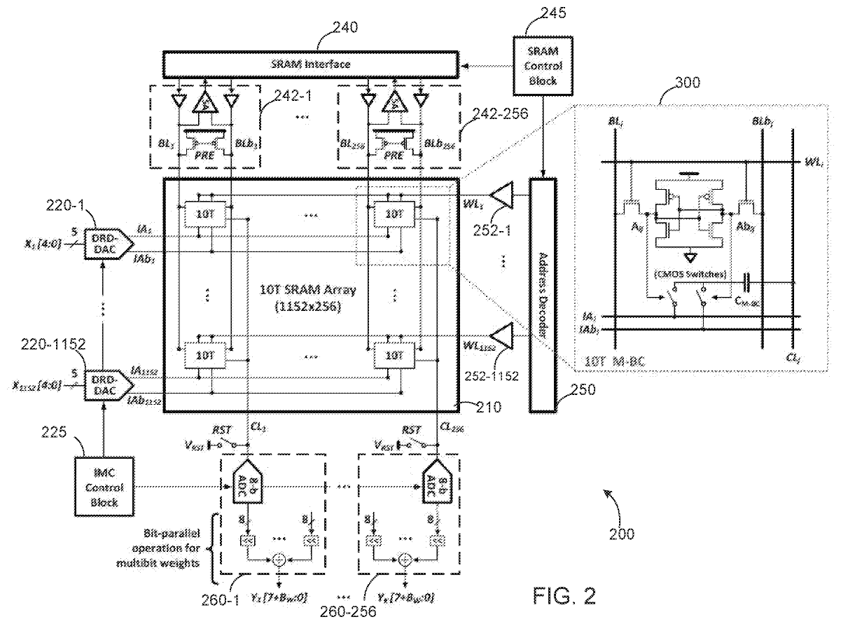

FIG. 2 depicts a block diagram of a fully row/column-parallel (1152 row×256 col) array of multiplying bit-cells (M-BCs) of an in-memory-computing (IMC) macro enabling N-bit (5-bit) input processing in accordance with an embodiment.

The exemplary IMC macro of FIG. 2, which may be used to implement structures such as the compute-in-memory array (CIMA) structures previously discussed, was rendered via a 28 nm fabrication process and is configured for providing fully row/column-parallel matrix-vector multiplication (MVM), for exploiting precision analog computation based on metal-fringing (wire) capacitors, for extending the binary input-vector elements to 5 bit (5-b) input-vector elements, and for increasing energy efficiency by approximately 16× and throughput by 5× as compared with IMC and CIMA embodiments discussed above.

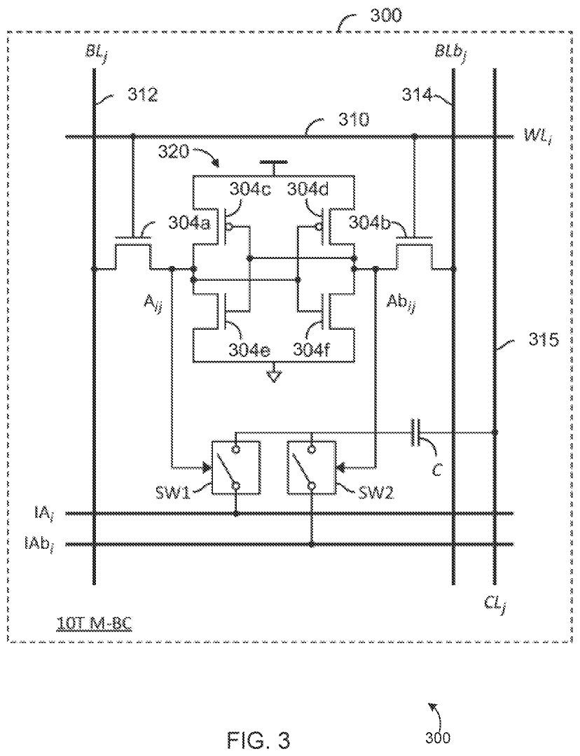

It is noted that the embodiments of FIGS. 2-3 implement MVM operations, which dominate compute-intensive and data-intensive AI workloads, in a manner that reduces compute energy and data movement by orders of magnitude. This is achieved through efficient analog compute in bit cells, and by thus accessing a compute result (e.g., inner product), rather than individual bits, from memory. But, doing so fundamentally instates an energy/throughput-vs.-SNR tradeoff, where going to analog introduces compute noise and accessing a compute result increases dynamic range (i.e., reducing SNR for given readout architecture).

Advantageously, IMC based on metal-fringing capacitors achieve very low noise from analog nonidealities, and thus potential for extremely high dynamic range. At least some of the embodiments exploit this precise capacitor-based compute mechanism to reliably enable the improved dynamic range such as discussed herein.

FIG. 2 shows a block diagram of an in-memory-computing macro 200 comprising: a 1152 (row)×256 (col.) array 210 of 10T SRAM multiplying bit cells (M-BCs); periphery for standard writing/reading thereto (e.g., a bit line (BL) decoder 240 and 256 BL drivers 242-1 through 242-256, a word line (WL) decoder 250 and 1152 WL drivers 252-1 through 252-1152, and control block 245 for controlling the decoders 240/250); periphery for providing 5-bit input-vector elements thereto (e.g., 1152 Dynamic-Range Doubling (DRD) DACs 220-1 through 220-1152, and a corresponding controller 225); periphery for digitizing the compute result from each column (e.g., 256 8-bit SAR ADCs 260-1 through 260-256), and column reset mechanisms 265-1 through 265-256 (e.g., CMOS switches configured to pull the output voltage levels of column compute lines CLs to a reset voltage V_{RST} during a reset phase of operation, and allow the voltage levels of column compute lines CLs to reflect their respective compute results during an evaluation phase of operation).

The array 210 of 10T SRAM multiplying bit cells (M-BCs) of IMC macro 200 operates in a manner similar to that described above with respect to the various figures. In particular, while writing/reading is typically performed row-by-row, MVM operations are typically performed by applying input-vector elements corresponding to neural-network input activations to all or several rows at once. That is, each DRD-DAC 220ⱼ, in response to a respective 5-bit input-vector element Xⱼ[4:0], generates a respective differential output signal (IAⱼ/IAbⱼ) which is subjected to a 1-bit multiplication with the stored weights (Wᵢⱼ/Wbᵢⱼ) at each M-BCⱼ in the corresponding row of M-BCs, and accumulation through charge-redistribution across M-BC capacitors on the compute line (CL) to yield an inner product in each column, which is then digitized via the respective ADC 260 of each column. The operation of individual 10T SRAM M-BCs forming the array 210 will be discussed in more detail below with respect to FIG. 3.

FIG. 3 depicts a circuit architecture of a multiplying bit-cell (M-BCs) according to an embodiment and suitable for use in implementing the 10T SRAM M-BCs of FIG. 2, as well similar array elements as described above with respect to the various figures. The M-BC 300 of FIG. 3 comprises a highly dense structure for achieving weight storage and multiplication, thereby minimizing data-broad-cast distance and control signals within the context of i-row, j-column arrays implemented using such M-BCs, such as the 1152 (row)×256 (col.) array 210 of 10T SRAM multiplying bit cells (M-BCs).

The exemplary M-BC 300 includes a six-transistor bit cell portion 320, a first switch SW1, a second switch SW2, a capacitor C, a word line (WL) 210, a first bit line (BLj) 312, a second bit line (BLbj) 314, and a compute line (CL) 315.

The six-transistor bit cell portion 320 is depicted as being located in a middle portion of the M-BC 300, and includes six transistors 304a-304f. The 6-transistor bit cell portion 320 can be used for storage, and to read and write data. In one example, the 6-transistor bit cell portion 320 stores the filter weight. In some examples, data is written to the M-BC 300 through the word line (WL) 310, the first bit line (BL) 312, and the second bit line (BLb) 314.

The multiplying bit-cell 300 includes first CMOS switch SW1 and second CMOS switch SW2. First switch SW1 is depicted as being controlled by a first activation signal A (Aᵢⱼ) such that, when closed, SW1 couples one of the received differential output signals provided by the DRD-DAC 220, illustratively IA, to a first terminal of the capacitor C. Second switch SW2 is depicted as being controlled by a second activation signal Ab (Abᵢⱼ) such that, when closed, SW2 couples the other one of the received differential output signals of the corresponding DRD-DAC 220, illustratively IAb, to the first terminal of the capacitor C. The second terminal of the capacitor C is connected to a compute line (CL). It is noted that in various other embodiments, the input signals provided to the switches SW1 and SW2 may comprise a fixed voltage (e.g., V_{dd}), ground, or some other voltage level.

The M-BC 300, including the first SW1 and second SW2 switches, can implement computation on the data stored in the 6-transistor bit cell portion 320. The result of a computation is driven as charge on the capacitor C. According to various implementations, the capacitor C may be is positioned above the bit cell 300 and utilize no additional area on the circuit. In some implementations, a logic value of either V_{dd} or ground is driven on the capacitor C. In other embodiments, the voltage driven on the capacitor C may comprise a positive or negative voltage in accordance with the operation of switches SW1 and SW2, and the output voltage level generated by the corresponding DRD-DAC 220.

Thus, the charge (as a function of the driven voltage) that is stored on the capacitor C is highly stable, since the capacitor C value itself is highly stable and the driven voltage is highly stable (e.g., driven up to the supply voltage or down to ground). In some examples, the capacitor C is a metal-oxide-metal (MOM) finger capacitor, and in some examples, the capacitor C is a 1.2 fF MOM capacitor. MOM capacitors have very good matching temperature and process characteristics, and thus have highly linear and stable compute operations. Note that other types of logic functions can be implemented using the M-BCs by changing the way the transistors 304 and/or switches SW1 and SW2 are connected and/or operated during the reset and evaluation phases of M-BC operation.

In various implementations, the 6-transistor bit cell portion 320 is implemented using different numbers of transistors, and may have different architectures. In some examples, the bit cell portion 320 can be a SRAM, DRAM, MRAM, or an RRAM.

### Improved IMC Accumulation and Scaling of M-BC Outputs

As depicted above with respect to FIG. 2, the N=5 (5-bit) input processing in-memory-computing (IMC) macro 200 contemplates a fully row/column-parallel (1152 row×256 col) array of multiplying bit-cells (M-BCs), such as the M-BC 300 as depicted above with respect to FIG. 3. It is further noted that the IMC macro 200 is depicted as using one 8-bit analog to digital converter (ADC) for each of the columns of connected M-BCs within the array 210. That is, the analog output signal provided by each of the illustratively 256 columns is individually converted by a respective 8-bit ADC to a respective 8-bit digital representation prior to further processing as discussed above and in the various related patent applications.

In particular, the various embodiments will be now described within the context of an IMC architecture configured to combine the outputs of multiple parallel columns, such as in the case where multiplication is required with multi-bit data stored in the bit cells, but where the bit precision cannot be accommodated within a single bit cell. In this case, bit-parallel processing can be employed, where the most-significant bit of the stored data is in the bit cells of one column, the next most-significant bit of the stored data is in the bit cells of the next column, and so on, all the way down to the least-significant bit of the stored data (typically bits of a stored data element will all be in the same row). In this case, each of the columns represents a component corresponding to a particular bit weighting of the computation output. Due to the linear nature of multiply-accumulate operations, the overall computation output can thus be derived by scaling each column output with a properly binary-weighted co-efficient, and then summing the different scaled column-output components. In general, the bit-weighting of data stored in the different columns need not be binary; this is readily supported by applying a corresponding scaling coefficient (not necessarily binary weighted) to each column output.

The scaling and summation of computational result indicative outputs of multiple parallel columns or bit lines may be performed prior to or after the ADC. If done before the ADC, the scaling and summing operations must be applied on the corresponding analog signal, which could be a voltage, current, charge, etc.

For example, within the context of an in-memory computing (IMC) array of bit-cells configured to multiple two vectors (or a vector and a scalar), each element from V1 is multiplied by each element from V2 and the totals are accumulated to achieve a result. Multiple bits of a vector V1 stored in memory are is mapped to multiple columns, and input bits of input vector V2 are sequential provided to each of the columns for iterations of multiplication and bit shifting. Each column (in this example) comprises the respective total voltage or stored charge associated with a weighted result (e.g., a bit position within a multiple bit word), illustratively a binary weighted result such as a 4-bit binary word (MSB, MSB-1, MSB-2, LSB) representing the result of a 4-bit input vector V2 being multiplied by each of the elements of a stored vector V1.

Rather than performing bit-shifting in the digital domain after A/D conversion of the columns to resolve the multiplication result (e.g., result of all input vector elements multiplied by all stored vector elements), various embodiments provide for an analog domain scaling of the total voltage or stored charge associated with each column in accordance with its column weighting or scaling factor (e.g., bit position), an accumulation of the scaled voltage/charge of each column to provide an analog representation of the multiplication result (e.g., an analog voltage/charge level representing the result of the 4-bit input vector V2 being multiplied by each of the elements of a stored vector V1), which accumulate voltage/charge level is then subjected to A/D conversion to provide a digital representation of the final multiplication result. For example, for a 4 bit input vector, instead of doing 4 cycles of bit parallel bit serial operation, the 4 bits are represented by an analog level and only one cycle is needed.

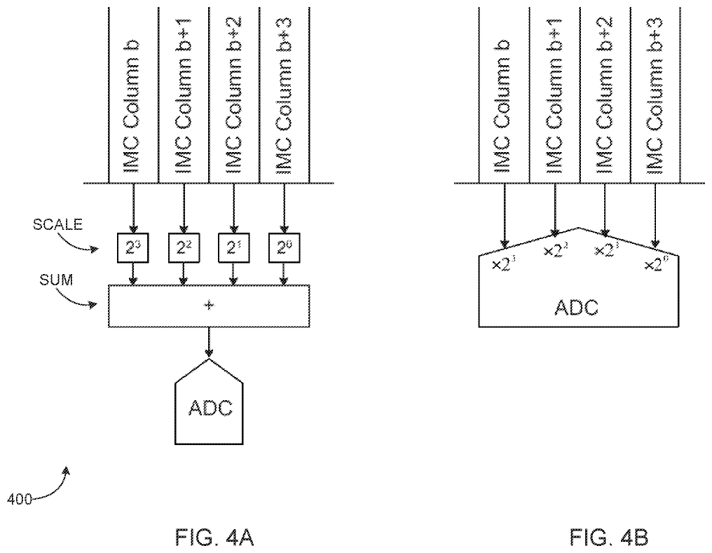

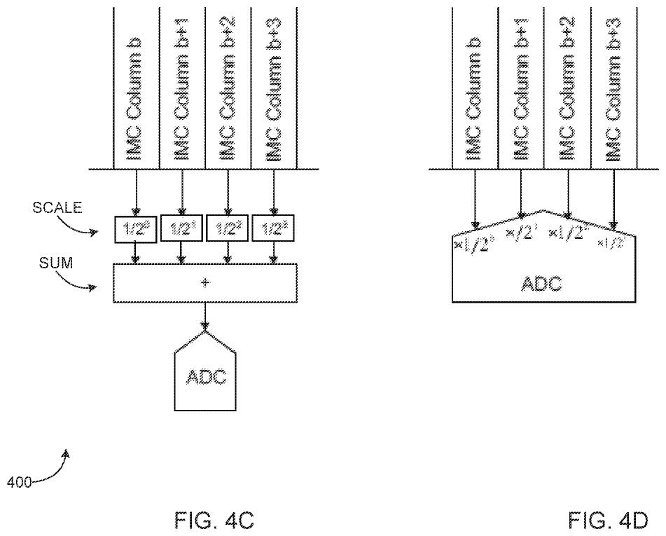

FIGS. 4A-4B graphically depict mechanisms for scaling and summation of computational result indicative outputs useful in illustrating the various embodiments.

Specifically, each of the mechanisms is depicted as scaling and summing four computational result indicative outputs, where each output represents a respective one of four columns or bit lines presenting a voltage level associated with charge stored on a respective column of connected bit-cell output capacitors, the voltage level representing a respective weighted portion of an accumulated result such as binary-weighted portion of the accumulated result. As depicted, four columns b, b+1, b+2, b+3 represent binary-weighted data of an accumulated 4-bit computational result where the most significant bit (MSB) is represented by column b and the least significant bit (LSB) by column b+3.

As depicted in FIGS. 4A-4B, and as generally described herein, each of four IMC columns (IMCb through IMCb+3) provides a respective voltage signal or voltage level stored across a respective plurality of bit cell output capacitors forming the column, and representing a respective binary weighted portion of an accumulated result.

In various embodiments, instead of a voltage signal/level, each of four IMC columns (IMCb through IMCb+3) may provide a current signal/level or some other type of signal/level to represent for each IMC column the respective binary weighted portion of the accumulated result (e.g., a signal such as a current or voltage signal provided by a buffer circuit, or by a resistor or transistor based voltage or charge divider circuit rather than an IMC output capacitor and/or capacitor-based voltage or charge divider circuit, etc.). Further, rather than using binary weighted and/or scaling, other embodiments may use other types of weighting and/or scaling depending upon the application, the components selected for the IMC, and/or other factors. Thus, various embodiments provide a mechanism for selectively attenuating or amplifying the weighted signals (or whatever type used) according to their weighting factors so as to provide, after summation, a total signal level (voltage level, current level, charge level, etc.) representative of the accumulated result. The mechanism of FIG. 4A contemplates scaling and summation of accumulated weighted portions of a computational result prior to ADC processing.

As depicted in FIG. 4A and generally described herein, each of four IMC columns (IMCb through IMCb+3) provides a respective voltage signal or voltage level stored across a respective plurality of bit cell output capacitors forming the column, and representing a respective binary weighted portion of an accumulated result. These voltage signals/levels are scaled to reflect their respective binary weighting with respect to each other. Specifically, the LSB column (b+3) is multiplied by a scaling factor of 2⁰=1, the next column (b+2) by a scaling factor of 2¹=2, the next column (b+1) by a scaling factor of 2²=4, and the final column (b) by a scaling factor of 2³=8. The scaled voltage levels are then summed together to provide a voltage level representing the accumulated result, which is converted to a digital representation by an ADC converter.

The mechanism of FIG. 4B contemplates scaling and summation of accumulated weighted portions of a computational result in conjunction with ADC processing. Specifically, the scaling and summation functions discussed with respect to FIG. 4A are implemented by modifying various parameters of the operation of the ADC, as will be described in more detail below.

It should be noted that while FIGS. 4A-4B illustrate the case where four columns are combined before or within the ADC, in general any number of columns may be combined in this manner. Further, such scaling and summing before/within the ADC can be combined with scaling and summing across any number of outputs after the ADC; this involves applying and digital scaling co-efficient (which reduces to bit-wise shifting for binary weighting) and summing in the digital domain. In addition to optimizing for implementation practicalities, as described below, this enables quantization-error effects to be optimally managed.

FIGS. 4C-4D graphically depict mechanisms for scaling and summation of computational result indicative outputs useful in illustrating the various embodiments. The discussion above with respect to FIGS. 4A-4B is generally applicable to FIGS. 4C-4D. It is noted that FIGS. 4C-4D contemplate a scaling function wherein the LSB column (b+3) is multiplied by a scaling factor of ½⁰, the next column (b+2) by a scaling factor of ½¹, the next column (b+1) by a scaling factor of ½², and the final column (b) by a scaling factor of ½³. The scaled voltage levels are then summed together to provide a voltage level representing the accumulated result, which is converted to a digital representation by an ADC converter.

### Capacitor-Based Analog Scaling and Summing

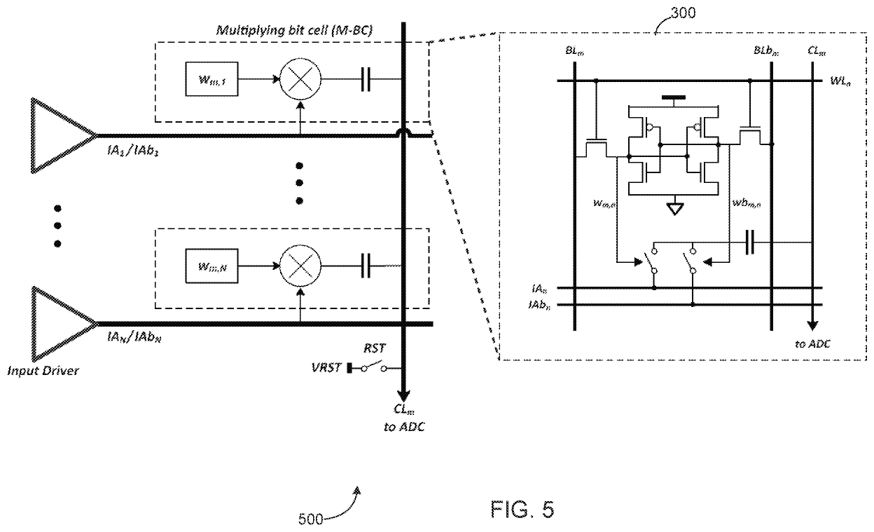

FIG. 5 graphically illustrates an exemplary IMC column within an array of M-BCs. As depicted in FIG. 5, each of a column of M-BCs 300 (1 through N) performs a multiplication of an input (IA₁/IAb₁ through IA_{N}/IAb_{N}) by a weighted value (W_{b,1} through W_{b,N}) to provide a respective result as an output voltage stored upon a respective output capacitor, which may be selectively couped to the output column line CL_{b}. In particular, FIG. 5 depicts the use of switched capacitors, whereby a column accumulation (reduction) operation is performed via charge redistribution across capacitors in a particular column. Essentially, individual bit-cell capacitors form the legs of a signal divider circuit such as a voltage/charge divider circuit, causing the output voltage (i.e., node coupling all capacitors) to settle to the average across the voltage/charge divider inputs (i.e., driven side of the legs). Such an average provides a scaled/normalized version of the accumulation, where the scaling factor is set by the total capacitance across which the charge is distributed (i.e., V=Q/C). As a result, scaling and summation of column output voltages can be achieved by setting the capacitance involved, and then shorting together the involved column capacitances across the columns.

According to various embodiments, a capacitor-based analog scaling and summing may be achieved via several approaches as will be discussed below; illustratively, (1) setting and shorting of the column capacitances, and (2) sampling the column voltages on auxiliary capacitance, and then setting and shorting the auxiliary capacitances (where the auxiliary capacitance may be combined with the ADC sample-and-hold circuit).

### Setting and Shorting Column Capacitances

Capacitance-based IMC typically involves two phases: (1) resetting, where the charge on all capacitors is reset by shorting the coupled node of the capacitors to a particular reference voltage; (2) evaluation, where the coupled node of the capacitors is released from shorting to the reference voltage, and the input legs of the signal divider circuit such as a voltage/charge divider circuit are driven (through the bit cells). Following this, each column output voltage can be sampled by an ADC for subsequent digitization.

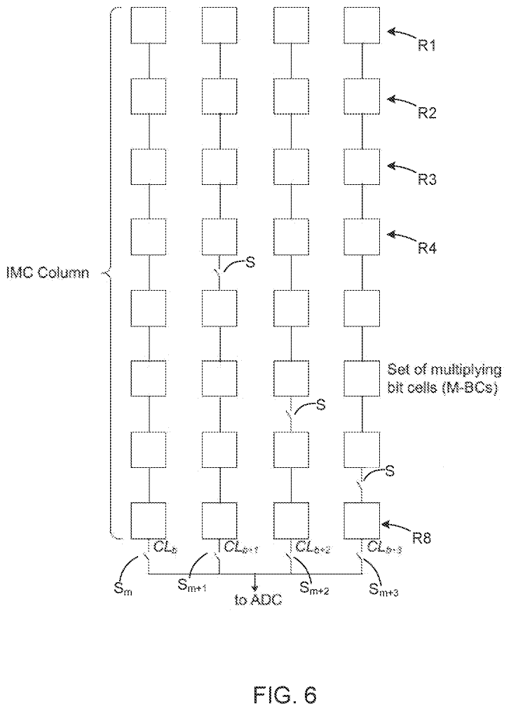

For analog scaling and shorting across columns before the ADC, an additional phase can be added, which is denoted herein as scaling. After the column output voltages settle, coupling across all the column capacitors can be broken, to yield a remaining capacitance of scaled amount across the columns to be shorted together. Then, the shorted capacitance across the columns can be sampled by an ADC for digitization. This approach is depicted in FIG. 6 for the case of binary-weighted scaling, as an example.

FIG. 6 graphically depicts an example of binary-weighted scaling within the bit-cell array of an in-memory computing architecture useful in understanding the embodiments. Specifically, FIG. 6 depicts an illustrative array of bit cell output capacitors for eight IMC rows (R1 through R8) by four IMC columns (CL_{b} through CL_{b+3}) of multiplying bit-cells, each of the IMC columns being selectively coupled to an input of an ADC via a respective switch (S_{b} through S_{b+3}). The array further includes additional switches S at each of CL_{b+3} between rows R7 and R8, CL_{b+2} between rows R6 and R7, and CL_{b+1} between rows R4 and R5. The additional switches S are introduced into the columns at these locations to break/allow coupling of some of the column capacitors at different points in the columns.

During each of a reset phase of operation and an evaluation phase of operation, the additional switches S are closed, thereby enabling coupling of all capacitances in a column. During a scaling phase of operation, the additional switches S are opened and the remaining column capacitances are shorted together by the column switches S_{b} through S_{b+3} and the resulting signal provided to the ADC.

It is noted that where the capacitance C of each output capacitor is substantially the same, the use of the additional switches S results in greater charge contributions to a subsequent signal voltage for those columns having more output capacitors. As such, column CL_{b} with eight bit-cell capacitors is effectively weighted as twice that of column CL_{b+1} with four bit-cell capacitors, which is effectively weighted as twice that of column CL_{b+2} with two bit-cell capacitors, which is effectively weighted as twice that of column CL_{b+3} with one bit-cell capacitor.

Given the charge-weighting due to the use of the additional switches S, the resulting voltage signal applied to the ADC represents a scaled accumulated output signal and can be digitized directly by the ADC to provide the digital representation of the accumulated output signal.

The inventor notes that introducing switches (whether for breaking column-capacitor coupling, or for enabling shorting across the column capacitances) adds parasitic capacitances, and these parasitic capacitances should also be properly weighted (binary or otherwise) for accurate scaling and summation across the columns. As such, in various embodiments parasitic offset switches S_{PO} or other structures are added to the array to balance the total switch-related parasitic capacitances in the columns.

The parasitic offset switches S_{PO} or other structures my comprise functioning or non-functioning switches. For example, for each additional switch S functioning as described above in a column, a similar functioning or non-functioning (e.g., always closed) switch may be included in the substrate (e.g., VLSI substrate) used to form the bit-cell array.

Thus, in some embodiments where binary weighting is used, in addition to the additional switches S operative in a column to effect weighting as described herein, one or more of the other columns has formed into a corresponding location a parasitic offset switch S_{PO} of similar structure such that column-to-column differences in capacitance are avoided. This technique may also be used with embodiments implementing weighting schemes other than binary weighting. The number and location of parasitic offset switches S_{PO} may be modified according to fabrication technology and other factors, all that is relevant is that the parasitic offset switches S_{PO} be formed in such a manner as to balance or offset the parasitic capacitances imparted to the circuitry by the additional switches S so as to avoid related scaling errors to the extent possible.

### Sampling, Setting, and Shorting Auxiliary Capacitances

In other embodiments, rather than using the same capacitors for column computation as well as the cross-column scaling operation, the voltage of each set of column capacitors is first sampled via an auxiliary sampling capacitor within a signal divider circuit such as a voltage/charge divider circuit (i.e., a capacitor network configured for charge sharing/sampling), wherein the auxiliary sampling capacitor associated with a column has a value selected to produce a scaled output as appropriate to that column. The sampling capacitor may comprise an extra capacitor formed for each column, a sample-and-hold capacitor of the ADC itself (integrated within the ADC or separate from the ADC), or some other capacitor.

In these embodiments, signal associated with a particular column is sampled via the auxiliary capacitor of a charge divider circuit associated with that column, which capacitor may be selectively coupled to that column or divider circuit.

Various embodiments contemplate the processing of signal associated with each column via a weighted input ADC; that is, an ADC with multiple inputs where each of those inputs may be weighted and the resulting weighted signals summed for ADC processing to provide thereby a digital output signal.

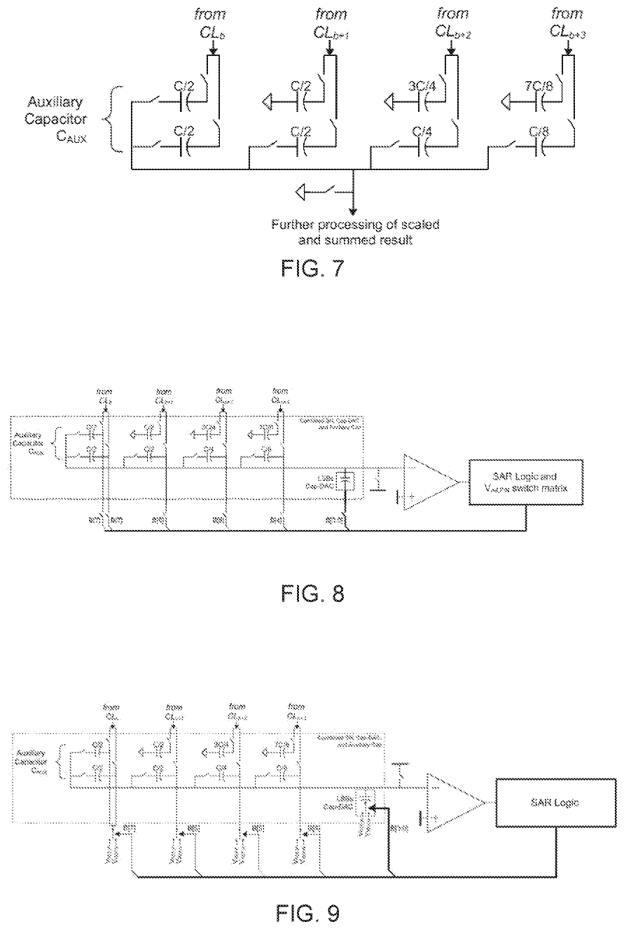

FIGS. 7-9 depict circuit diagrams of various embodiments of binary-weighted scaling proximate or within an output ADC of an in-memory computing architecture. It is noted that while the embodiments of FIGS. 7-9 are generally depicted and described as processing voltage signals provided by charge stored across bit cell output capacitors such as described above, the embodiments may also be used to process other types of signals (e.g., voltage, current, etc.) such as previously discussed with respect to FIGS. 4A-4B.

FIG. 7 depicts a circuit diagram useful in understanding various embodiments. Specifically, the circuit 700 of FIG. 7 contemplates a plurality of capacitive circuits (e.g., four), each capacitive circuit operative to share a portion of charge stored across a respective plurality of bit cell output capacitors with respective sampling or auxiliary capacitor(s) to provide thereat a respective voltage output signal representative of a respective weighted portion of an accumulated result, wherein a voltage sampled across a sampling or auxiliary capacitor(s) is provided to the ADC for further processing.

It is important to note that the sampling operation on the auxiliary capacitors is achieved through a charge-sharing operation. Thus, sampling results in scaling of the sampled voltage by a factor of C_{COL}/(C_{COL}+C_{AUX}), where C_{COL} is the total column capacitance and C_{AUX} is the auxiliary sampling capacitance. This makes it important to ensure that C_{COL} and C_{AUX} are well matched across the columns and that C_{AUX} be adequately discharged at the start, to alleviate errors. Then, C_{AUX} is subsequently broken into binary-weighted components, so that the properly binary-weighted components are then shorted together for accurate scaling and summing.

Specifically, the capacitance of the charge divider circuits (signal divider circuits more broadly) is important where sharing capacitance is a mechanism of scaling (binary weighted or otherwise) in the case of a charge sharing event, such as sharing of charge stored across a plurality of bit-cell output capacitors with a corresponding capacitor voltage/charge divider circuit. In this case, load balancing capacitors are used (such as depicted in FIGS. 7-9) to ensure that each capacitor charge divider circuit has substantially the same capacitance.

Rather than charge sharing, in various embodiments scaling is achieved by other means alone or in combination. For example, in various embodiments, scaling of each weighted-data-representative analog signal may be achieved via charge, voltage, current, or impedance scaling techniques depending upon the nature of the analog signal to be scaled (e.g., using weighted or binary weighted capacitor divider networks, resistor divider networks, and so on). As most frequently depicted herein, various examples provide charge divider circuits based on capacitive charge sharing or redistribution so as to scale charge-based or voltage-based weighted-data-representative analog signals.

Generally speaking, each of a plurality of weighted-data-representative analog signals (e.g., binary weighted by column) is scaled such that the analog signal contribution (charge, voltage, current, etc.) of a particular weighted-data-representative analog signal to the total or accumulated signal level of all the various weighted-data-representative analog signals is proportional to the weight of that data-representative analog signal (e.g., the weight associated with the column position of that data-representative analog signal).

For example, if bit-cell computation outputs are provided through resistive/conductive output impedance (rather than capacitive) then the scaling circuits may comprise resistive scaling or signal dividing components, transistor scaling or signal dividing components, or some other scaling or signal dividing components suitable for indicating respective weighting/scaling of charge levels or signals indicative of charge levels (e.g., voltage/charge divider circuit, charge sharing network, and the like). In this case, the load-balancing capacitors need not be used, since the settled signal does not depend upon capacitive loading.

In this binary weighting example, the sampled signal from column CL_{b} is given twice the weight as that of column CL_{b+1}, which is given twice the weight as that of column CL_{b+2}, which is given twice the weight as that of column CL_{b+3}. As such, as can be seen by inspection of FIG. 7, the various switches are controlled to cause the capacitance of the voltage/charge divider circuit for each column to be the same (i.e., C), but the sampling or auxiliary capacitor for each voltage/charge divider circuit is different. Specifically, the sampling or auxiliary capacitor for column CL_{b} is C (C/2+C/2), for column CL_{b+1} is C/2, for column CL_{b+2} is C/4, and for column CL_{b+3} is C/8. The signal present on each of the sampling or auxiliary capacitors represents the respective scaled portion of the accumulated result, and by connecting each of the sampling or auxiliary capacitors of the columns together and providing that signal to the ADC a digital representation of the accumulated result may be generated. As depicted, the capacitance of the voltage/charge divider circuit for each column to be the same so that the error from a charge sharing event is equalized across the voltage/charge divider circuits so as to avoid any relative error between the voltage/charge divider circuits.

FIG. 8 depicts a circuit diagram useful in understanding various embodiments. Specifically, FIGS. 8-9 depict the voltage/charge divider circuitry of FIG. 7, wherein the voltage sampled across all the sampling or auxiliary capacitors is combined during a charge sharing event (e.g., during a measurement or evaluation phase of operation) into the sample-and-hold (SH) of a successive-approximation-register (SAR) ADC, wherein the SH also serves as a feedback digital-to-analog converter (DAC). This approach enables a compact layout, which is desirable for IMC readout ADCs.

It is noted that FIGS. 8-9 depict an 8-bit ADC receiving an accumulated input voltage associated with only four weighted input signals. If eight weighted input signals were processed by the 8-bit ADC, then each of the eight weighted input signals would be initially scaled by a respective divider circuit. In the case of using capacitor divider circuits, the capacitance of each of the additional four (e.g., LSB) voltage/charge divider circuits would also be the same as the initial four (e.g., MSB) voltage/charge divider circuits, and the respective sampling or auxiliary capacitors would be scaled accordingly (e.g., C/16, C/32, C/64, AND C/128 assuming four columns representing the next four LSB values of an accumulated result).

Within the context of the S/H SAR ADC of FIGS. 8-9, the S/H is integrated into the ADC. The SAR ADC comprises a feedback circuit wherein a digital to analog converter (DAC) is adjusted via differing digital input signals provided by SAR logic to ultimately produce a DAC output voltage that corresponds to the analog input voltage provided to the ADC, thereby determining the digital word or bits representing the analog input voltage to the ADC.

The analog input voltage is sampled at the bottom plate of each of the sampling capacitors of each voltage/charge divider circuit (i.e., capacitors denoted as C, C/2, C/4 and C/8). The voltage associated with the feedback code of the DAC is then successively applied to the other plate of the capacitors and, in doing so, causes a binary weighted signal to be produced thereat for comparison purposes (i.e., for determining the ADC output value).

The circuit 800 of FIG. 8 contemplates that an ADC SH/DAC is partitioned into four segments, for taking inputs from four IMC columns, as an example. Each of the four segments has equal capacitance, to ensure the relative sampling error/scaling is not significant. Each of the four segments is then further divided into a portion that is processed by the ADC for digitization, and a portion that is not processed. The portion that is further processed corresponds to a binary-weighted capacitance across the columns. Each column output is sampled onto one side of each segment, and only the portions that are further processed are then subsequently coupled together on the other side. The remaining portion is left uncoupled (remaining shorted to at a reference voltage) on the other side, and is subsequently discharged before future sampling.

Coupling the segment portions in this way, results in scaling and summing of the column outputs within the ADC SH/DAC. SAR digitization then proceeds in the standard manner, yielding a final digital output code. As one example, the scaled and summed charge is sampled on one end of the SH/DAC, while the other end is driven by fed-back digital control signals. This causes the fed-back digital control signals to yield corresponding negative voltage shifts on the signal fed to a comparator. When the negative voltage shifts cancel the voltage due to the sampled charge (i.e., by bringing the comparator voltage back to a fixed reference), the final digital output code is thereby obtained. Other forms of SAR digitization can also be employed, such as where the DAC is separated from the S/H.

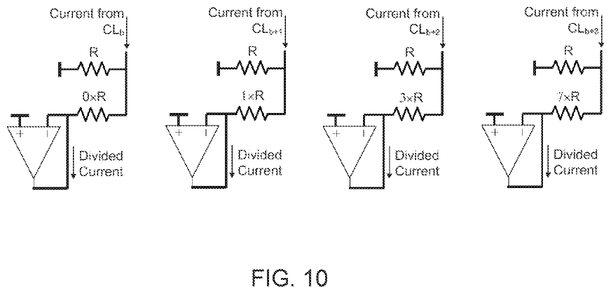

FIG. 10 depicts circuit diagrams of various embodiments of binary-weighted current divider scaling circuitry suitable for use in the various embodiments. It can be seen that a weighted-data-representative analog signal from MSB column CL_{b} is effectively weighted as twice that of column CL_{b+1}, which is effectively weighted as twice that of column CL_{b+2}, which is effectively weighted as twice that of column CL_{b+3}.

### Benefits and Limitations

The above-described embodiments utilize approaches to scaling and summing before the ADC and have a primary benefit of the ADC being shared across summed columns within the context of in-memory computing embodiments. This allows the ADC energy and area consumption to be amortized.

The approach based on setting and shorting column capacitors has the specific advantage that no additional auxiliary capacitor is required. In the case where the auxiliary capacitor is combine with the ADC SH, the benefit is that the ADC complexity is not increased (a standard ADC can be used).

The approach based on sampling to an auxiliary capacitor (possibly integrated with the ADC SH and DAC) has the benefit that the additional scaling phase (after reset and evaluation) is not required, and the IMC architecture complexity is not increased (e.g., due to the addition of switches to make/break coupling between sets of the bit-cell capacitors).

Overall, the limitation of analog scaling summing is that the total dynamic range of the signal to be digitized by the ADC is increased. The ADC, which then performs quantization of the signal to a particular resolution, therefore introduces quantization error. The quantization error is mitigated somewhat relative to post-ADC scaling and summing, where each column output incurs quantization (i.e., the analog residue cannot be recovered after each column-output digitization, whereas pre-ADC scaling and summing incurs one quantization event); however, post-ADC scaling and summation has a net benefit on quantization error due to the low energy/area cost of digital bit-growth. The quantization error of pre-ADC scaling and summing can be reduced by increasing the ADC resolution, at the cost of ADC energy/area overhead.

The various embodiments, while primarily described within the context of binary-weighted scaling factors, are suitable for use in arbitrary analog scaling of columns values. That is, while the disclosure primarily describes a structure where the columns feeding a shared ADC have binary-weighted scaling factors, it should be understood that arbitrary scaling factors could be used.

Further, it should be understood that the scaling factors may be configurable. It is noted that a primary benefit of non-binary-weighted scaling factors is that that alternate number formats (i.e., non-binary integers) may then be used for the matrix weights stored in the memory cells. This is valuable because quantized neural networks may exploit alternate number formats (e.g., where bit positions represent powers of 1.5, 4, etc., instead of 2) to optimize how weight dynamic-range tradeoffs are managed.

Further, equal scaling factors may be used to increase the total charge signal relative to a single column computation. In this manner, mitigating the impacts of different sources of charge noise may be achieved.

Further, configurability of the scaling factor enables the above two features on a dynamic basis, where for instance different in-memory computations scheduled during execution time may be thus optimized. Such configurability requires configurable capacitor setting across the columns, which could be achieved using capacitive digital-to-analog converters (DACs) coupled to the different column outputs, thus providing digital configuration control.

The various embodiments contemplate compensating capacitance mismatch across columns. Specifically, in cases where column scaling is determined by the relative ratio of capacitances across the columns, deviations in the relative ratios due to parasitic capacitances can lead to computation errors. This is overcome in various embodiments via any of a plurality of practical approaches, as discussed herein.

For example, in some embodiments the critical capacitances are matched through careful layout and parasitic-capacitance estimation. In particular, the layout features impacting the parasitic capacitances is matched within the array and array periphery, such as on a substrate or layer of a very large scale integrated (VLSI) circuit during fabrication.

In the case of setting and shorting the columns capacitances, this should include consideration of the column switches used to make/break coupling connections between the column capacitances. As an example, this can be achieved either by introducing dummy MOSFET switches (which may be kept statically on or off) to match the parasitics of actual MOSFET switches in other columns, or by adjusting the geometries of the MOSFET switches so that they maintain the ratioed scaling intended across columns.

In the case of sampling, setting, and shorting auxiliary capacitances, this can be achieved by matching the layouts of connections (and surrounding features) from the columns to the auxiliary capacitances, and by matching the layouts of the auxiliary capacitances themselves.

Further, capacitance DACs may be coupled to each of the column outputs to enable trim-able capacitive loading that introduces linearly adjustable voltage attenuation, to compensate mismatches in the parasitic capacitances.

As described herein, some of the various embodiments are directed to IMC computing architecture, apparatus, methods, and portions thereof configured to acquire the computational result indicative outputs of multiple parallel columns or bit lines in a manner avoiding the use of individual analog-to-digital converters (ADCs) for each column or bit line. That is, rather than converting the analog output signal associated with each bit line or column to a respective digital representation suitable for further processing within the IMC computing architecture, the various embodiments perform some of this further processing using the analog output signals associated with the bit lines or columns so as to reduce the number of ADCs needed to implement the functions of the IMC computing architecture while retaining analog output signal accuracy (i.e., reducing the impact of ADC quantization errors and other errors).

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

While specific systems, apparatus, methodologies, mechanisms and the like have been disclosed as discussed above, it should be apparent to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. In addition, the references listed herein are also part of the application and are incorporated by reference in their entirety as if fully set forth herein.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof.

What is claimed is:

1. Apparatus for scaling and summing a plurality of weighted-data-representative analog signals, wherein each analog signal comprises a voltage associated with a respective plurality of coupled bit-cell outputs within an in-memory computing (IMC) array of bit-cells, the apparatus comprising:
a plurality of signal divider circuits, each signal divider circuit configured to process a respective weighted-data-representative analog signal to produce an output signal having a value scaled in accordance with the respective weighting value;
wherein, during a measurement phase of operation, the signal divider circuit output signals are coupled to an input of an analog to digital converter (ADC) configured to generate therefrom a digital output representing a summation of the weighted-data-representative analog signals.

2. The apparatus of claim 1, wherein the signal divider circuits comprise voltage divider circuits.

3. The apparatus of claim 1, wherein:
each bit-cell output is provided via a respective output capacitor; and
the signal divider circuits comprise charge divider circuits.

4. The apparatus of claim 3, wherein:
each analog signal represents a charge stored across a respective plurality of coupled bit-cell output capacitors within the IMC array of bit-cells; and
each of the plurality of signal divider circuits has a substantially similar total capacitance, and respective output capacitor having a capacitance selected to provide the corresponding scaled output signal in response to a transfer thereto of a portion of the charge stored across the respective plurality of coupled bit-cell output capacitors.

5. The apparatus of claim 2, wherein the signal divider circuit is integrated with a sample and hold circuit within the ADC.

6. The apparatus of claim 1, wherein the analog signals comprise N analog signals to be binary weighted, where N is an integer greater than 1, the apparatus comprising:
a least significant bit (LSB) signal divider circuit having a total capacitance of C and an output capacitor of C/2^{N-1}, the LSB signal divider circuit being configured to process a LSB-representative analog signal; and
a most significant bit (MSB) signal divider circuit having a total capacitance of C and an output capacitor of C, the MSB signal divider circuit being configured to process a MSB-representative analog signal.

7. The apparatus of claim 1, comprising:
a LSB+1 signal divider circuit having a total capacitance of C and an output capacitor of C/N, the LSB signal divider circuit being configured to process a LSB+1-representative analog signal; and
a most significant bit (MSB) signal divider circuit having a total capacitance of C and an output capacitor of C/2, the MSB signal divider circuit being configured to process a MSB-representative analog signal.

8. The apparatus of claim 3, wherein at least some of the columns of bit-cells disposed therein a respective disconnect switch for disconnecting a first portion of the column of bit cells from a remaining portion of the column of bit-cells such that an analog signal provided by the remaining portion of the column of bit-cells is scaled to a weighting associated with the column.

9. The apparatus of claim 8, further comprising a plurality of switches configured to couple the remaining portions of the columns of bit-cells to each other to provide thereby an analog signal representing a weighted accumulated result.

10. An analog scaling and summing apparatus for capacitor-based in-memory computing (IMC), wherein each bit-cell in a N×M array of bit-cells provides at a respective output capacitor a voltage level associated with a weighted respective portion of an IMC operation, wherein a column of bit-cell output capacitors storing voltage levels associated with the same weight are coupled together to provide for that weight a respective weighted-data-representative analog signal, the apparatus comprising:
a plurality of signal divider circuits, each signal divider circuit configured to process a respective weighted-data-representative analog signal of a respective column of bit-cell output capacitors to produce an output signal across a respective output capacitor of a capacitance value scaled in accordance with the respective weighting value;
wherein, during a measurement phase of operation, the output capacitors of the signal divider circuits are coupled to a sample and hold circuit associated with an input of an analog to digital converter (ADC) configured to generate therefrom a digital output representing a summation of the weighted-data-representative analog signals.

11. The apparatus of claim 10, wherein each column of weighted-data-representative analog signals represent respective binary-weighted data bits of an accumulated result of the IMC operation.

12. The apparatus of claim 11, wherein:
during a reset phase of operation, the charge stored in each of the columns of bit-cell output capacitors is substantially removed;
during an evaluate phase of operation, the charge stored in each of the columns of bit-cell output capacitors provides a corresponding contribution to a total charge of the respective column; and
during the measurement phase of operation, each of the weighted-data-representative analog signals is scaled in accordance with its weighting level to provide thereby a weighted portion of an analog signal representing an accumulated result to be processed by the ADC.

13. An analog scaling and summing apparatus for capacitor-based in-memory computing (IMC), wherein each bit-cell in a N×M array of bit-cells provides at a respective output capacitor a voltage level associated with a weighted respective portion of an IMC operation, wherein a column of bit-cell output capacitors storing voltage levels associated with the same weight are coupled together to provide for that weight a respective weighted-data-representative analog signal, the apparatus comprising:
a plurality of signal divider circuits, each signal divider circuit configured to process a respective weighted-data-representative analog signal to produce an output signal across a respective output capacitor selectively controlled by a successive approximation register (SAR) analog to digital converter (ADC); wherein
during a reset phase of operation, the charge stored in each of the columns of bit-cell output capacitors is substantially removed;
during an evaluate phase of operation, the charge stored in each of the columns of bit-cell output capacitors provides a corresponding contribution to a total charge of the respective column; and
during the measurement phase of operation, switches within one or more of the columns of bit-cell output capacitors are activated to disconnect at least a portion of the bit-cell output capacitors, wherein the remaining portions of bit-cell output capacitors for each column have a total capacitance reflecting the weighting value of the column, wherein the remaining coupled capacitors in each column are coupled together and to an input of the ADC.

14. Apparatus for scaling and summing a plurality of weighted-data-representative analog signals, wherein each weighted-data-representative analog signal comprises an electronic voltage, current, or charge provided by a respective column of coupled bit-cells within an in-memory computing (IMC) array of bit-cells, the apparatus comprising:
at least some of the columns of coupled bit-cells having disposed therein a respective disconnect switch for disconnecting a first portion of the column of bit cells from a remaining portion of the column of bit-cells such that analog signal provided by the remaining portion of the column of bit-cells is scaled to a weighting associated with the column; and
switches configured to couple the remaining portions of columns of bit-cells to each other to provide thereby an analog signal representing an accumulated result.

15. The apparatus of claim 14, wherein:
each of the bit-cells comprises an output capacitor for storing a charge indicative of a bit-cell operation; and
each of the bit-cell columns being associated with a respective data weighting value.

16. The apparatus of claim 15, wherein each column is associated with a remaining portion of bit-cell output capacitors proportional to the weight of the column.

17. The apparatus of claim 15, further comprising a plurality of parasitic offset switches S_{PO} configured to compensate for weighted parasitic capacitance of the disconnect switches.

18. The apparatus of claim 15, wherein the analog signals comprise N binary weighted analog signals, where N is an integer greater than 1, the apparatus comprising N columns of respective coupled bit-cell output capacitors within the IMC array.

19. The apparatus of claim 15, wherein the weighted-data-representative analog signals comprise at least most significant bit (MSB) and least significant bit (LSB) binary weighted data-representative analog signals.

20. The apparatus of claim 19, wherein the weighted-data-representative analog signals further comprise at least one additional binary weighted data-representative analog signal.
